(19) United States
(12) Patent Application Publication
(10) Pub. No.: US 2022/0360291 A1
(43) Pub. Date: Nov. 10, 2022

(54) EFFICIENT AMPLIFER OPERATION

(71) Applicant: Telefonaktiebolaget LM Ericsson (publ), Stockholm (SE)

(72) Inventors: Ulf GUSTAVSSON, Göteborg (SE); Yibo WU, Göteborgse (SE); Thomas ERIKSSON, Göteborg (SE)

(73) Assignee: Telefonaktiebolaget LM Ericsson (publ), Stockholm (SE)

(21) Appl. No.: 17/624,179

(22) PCT Filed: Oct. 8, 2019
(86) PCT No.: PCT/SE2019/050985

§ 371 Date: Dec. 30, 2021

Related U.S. Application Data
(60) Provisional application No. 62/869,135, filed on Jul. 1, 2019.

(51) Int. Cl. H04B 1/40; H03F 1/32; H03F 3/24; H04B 1/10; H04L 27/26

(52) U.S. Cl. CPC H04B 1/40; H03F 1/3258; H03F 3/245; H04B 1/10; H04L 27/2623; H03F 2200/451

(57) ABSTRACT

Efficient amplifier operation. In one aspect, there is a radio transceiver device. The radio transceiver device includes a distorting unit configured to receive an input signal and distort the received input signal, thereby producing a distorted input signal. The radio transceiver device further includes a limiter configured to receive the distorted input signal and produce a limited signal based on the received distorted input signal. The radio transceiver device further includes a power amplifier configured to receive the limited signal and amplify the limited signal, thereby producing an amplified limited signal.

### TECHNICAL FIELD

Disclosed are embodiments related to devices and methods for providing efficient amplifier operation.

### BACKGROUND

Modern communication systems struggle with energy efficiency. Reduction of peak-to-average power ratio (PAPR) is a common measure taken for improvement. The reduction of the PAPR, however, comes at the cost of increased computational complexity, latency, and error vector magnitude (EVM) in radio channel. For example, existing solutions of reducing the PAPR may result in increased EVM, which bottlenecks the performance of a radio transmitter in terms of throughput.

### SUMMARY

As higher modulation densities are introduced to achieve greater data-rates, potential reduction of the PAPR shrinks and potential energy saving from reducing the PAPR is therefore reduced. Accordingly, there is a need to increase average output power of a radio transmitter while operating the radio transmitter more efficiently.

According to some embodiments of this disclosure, a radio transceiver is provided. The radio transceiver may include a radio transmitter comprising a digital pre-distortion (DPD) unit, a power amplifier (PA), and a limiter between the output of the DPD and the input of the PA. By including the limiter between the DPD unit and the PA, average output power and operating efficiency of the PA may be increased while allowing the PA to perform closer to the lower bound of normalized mean squared error (NMSE).

According to some embodiments, there is provided a process performed by a radio transceiver device. The process may begin with receiving an input signal. The process may also include distorting the received input signal, thereby producing a distorted input signal, producing a limited signal based on the distorted input signal, and amplifying the limited signal, thereby producing an amplified limited signal.

### BRIEF DESCRIPTION OF THE DRAWINGS

The accompanying drawings, which are incorporated herein and form part of the specification, illustrate various embodiments.

FIG. 1A illustrates a wireless communication system according to some embodiments.

FIG. 1B shows a configuration of a radio transmitter.

FIG. 2 shows a configuration of a radio transmitter.

FIG. 3 shows a configuration of a radio transmitter according to some embodiments.

FIG. 4A illustrates NMSEs for different configurations.

FIG. 4B illustrates PAPR for different configurations.

FIG. 5 shows signals inputted to and/or outputted from various units included in the radio transmitter shown in FIG. 2.

FIG. 6A shows an exemplary configuration of a CFR unit.

FIGS. 6B and 6C show signals inputted to and/or outputted from various units included in a CFR unit.

FIG. 7 shows signals inputted to and/or outputted from various units included in the radio transmitter shown in FIG. 3.

FIG. 8 is a flow chart illustrating a process according to some embodiments.

### DETAILED DESCRIPTION

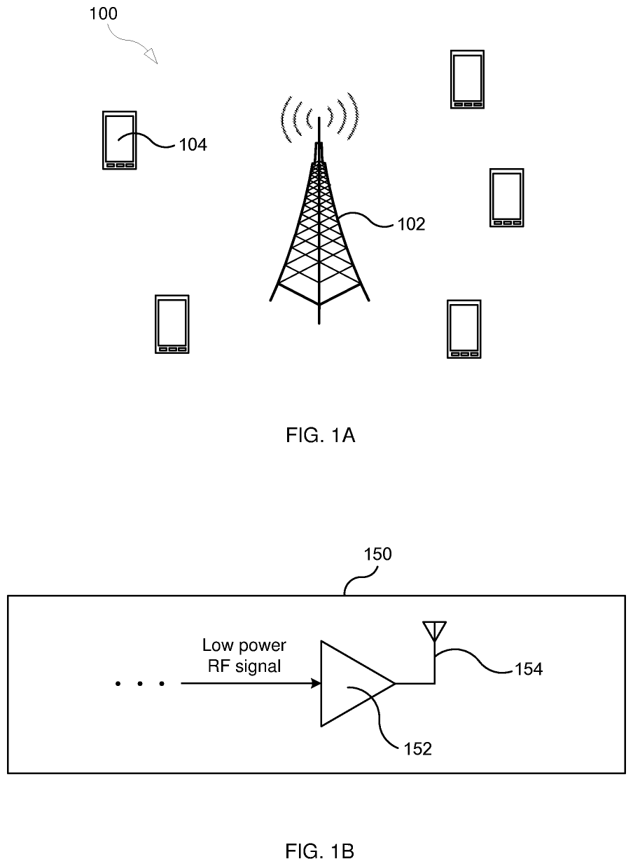

FIG. 1A illustrates a wireless communication system 100. The wireless communication system 100 may comprise a first radio transceiver 102 (e.g., a base station) and a second radio transceiver 104 (e.g., a smartphone, a smart appliance, a sensor, a tablet, or any other device capable of performing wireless communication with radio transceiver 102). Without limitation, radio transceiver 104 will be referred to herein as “user equipment (UE) 104” and radio transceiver device 102 will be referred to herein as “base station 102.”

The wireless communication system 100 may be any of Second/Third Generation (2G/3G) network, 3G Long Term Evolution (LTE) network, 4G network, Worldwide interoperability of Microwave Access (WiMAX) network, Wireless Local Area Network (WLAN), Fifth Generation Mobile network (5G), or any combination thereof

The base station 102 and/or the UE 104 may comprise a radio transmitter 150 shown in FIG. 1B. For example, the base station 102 may send data toward the UE 104 using the radio transmitter 150 included in the base station 102. Similarly, the UE 104 may send data toward the base station 102 using the radio transmitter 150 included in the UE 104.

As shown in FIG. 1B, the radio transmitter 150 may comprise a power amplifier (PA) 152 and an antenna arrangement 154 (e.g., one or more antennas). The PA 152 may receive a low power RF signal and amplify the received low power RF signal to a suitable level for wireless transmission. The low power RF signal may be generated by an Orthogonal Frequency-Division Multiplexing (OFDM) unit or other modulator. The amplified RF signal may be transmitted using the antenna arrangement 154. Even though FIG. 1B shows that the antenna arrangement 154 is directly connected to the PA 152, there may be other component(s) connected between the antenna 154 and the PA 152.

In operating a power amplifier, it is desirable to improve the operating efficiency of the power amplifier while reducing distortion caused by the operation of the power amplifier. One way of improving the operating efficiency and reducing the distortion is using a crest-factor reduction (CFR) unit and a digital pre-distortion (DPD) unit.

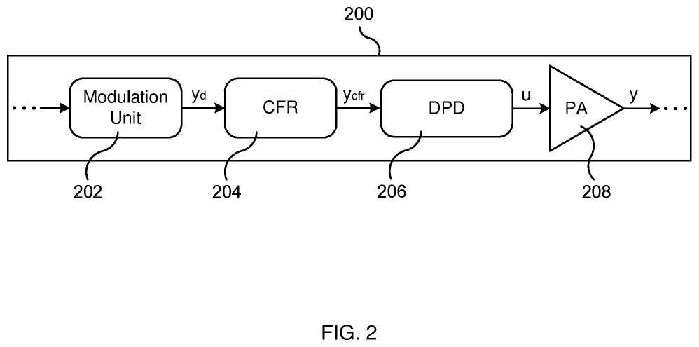

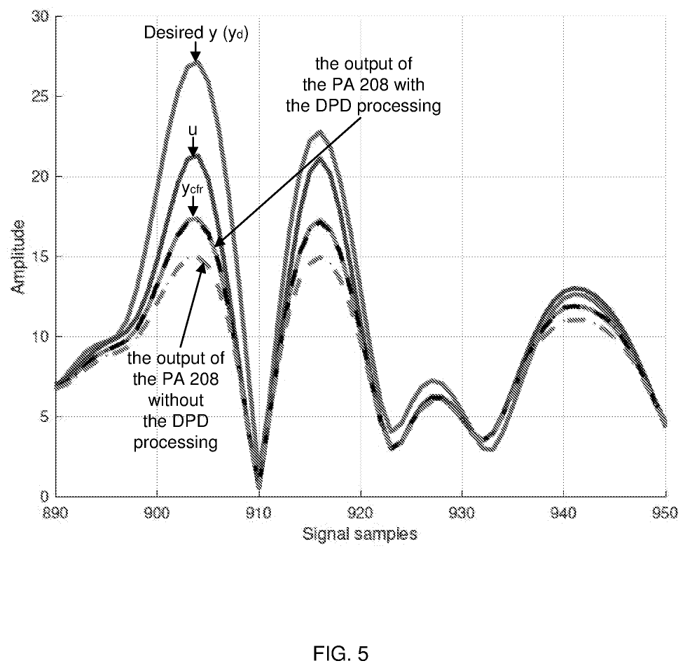

For example, as shown in FIG. 2, a radio transmitter 200 may comprise a modulation unit 202, a CFR unit 204, a DPD unit 206, and a PA 208. FIG. 5 shows exemplary signals inputted to and/or outputted from the modulation unit 202, the CFR unit 204, the DPD unit 206, and/or the PA 208. In FIG. 5, the power gain of the PA 208 is assumed to be 1 for the convenience of explanation.

In the exemplary radio transmitter 200 shown in FIG. 2, the modulation unit 202 is configured to output a signal y_{d}. The modulation unit 202 may be an Orthogonal Frequency-Division Multiplexing (OFDM) unit or other modulator.

In FIG. 5, the signal y_{d} corresponds to a signal outputted from the PA 208 because the power gain of the PA 208 is assumed to be 1 (thus the signal inputted to the PA 208 is ideally same as the signal outputted from the PA 208).

The CFR unit 204 is configured to receive the input signal y_{d} from the modulation unit 202 and to reduce the peak-to-average ratio of the input signal y_{d}, thereby producing a reduced signal (or a clipped signal) y_{cfr} that meets a desired crest factor requirement. For example, as shown in FIG. 5, the amplitude of the reduced signal y_{cfr} is substantially lower than the amplitude of the input signal y_{d}. In some embodiments, the CFR unit 204 may change a portion of the input signal yd such that the values of all portions of the input signal y_{d} have magnitudes that are equal to or less than a threshold value.

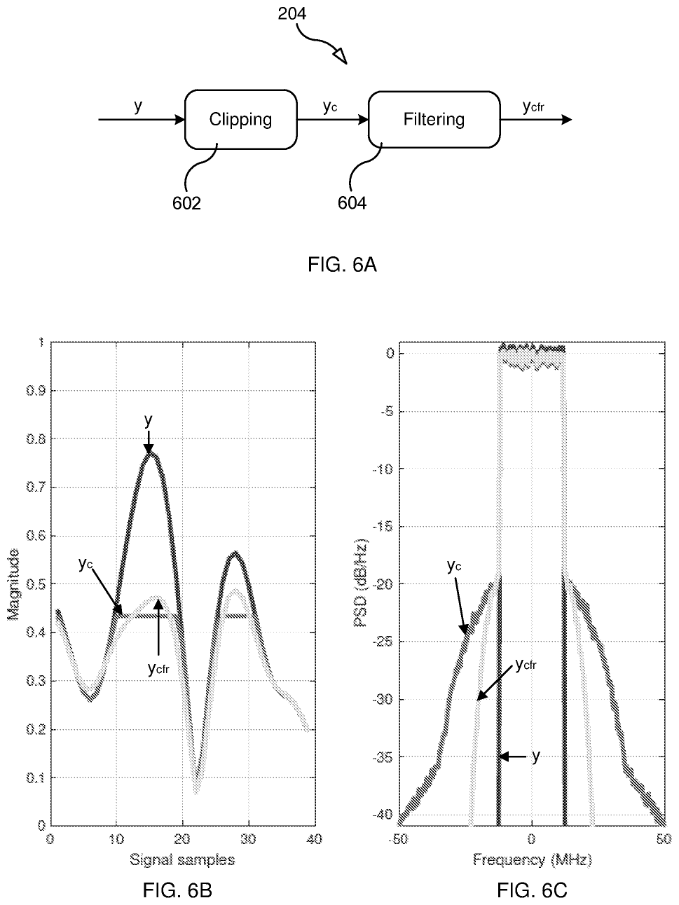

The CFR unit 204 may be designed in various ways. FIG. 6A shows an exemplary CFR unit 204 according to some embodiments. As shown in FIG. 6A, the CFR unit 204 may comprise a clipping unit 602 and a filtering unit 604.

The clipping unit 602 may perform a clipping function on an inputted signal y, and thus produces a clipped signal y_{c}. As shown in FIG. 6B, the clipping unit 602 makes the portion of the inputted signal y that is above a particular value (e.g., 0.43) to have the particular value (e.g., 0.43), in order to satisfy a desired crest factor requirement. But as shown in FIG. 6C, clipping the inputted signal y may introduce out-of-band distortions.

Accordingly, in the exemplary CFR unit 204, the clipped signal y_{c} is fed to the filtering unit 604. The filtering unit 604 may perform the function of restricting the out-of-band leakage as shown in FIG. 6C.

The DPD unit 206 may be configured to receive the reduced signal y_{cfr} and to apply a distortion process to the reduced signal y_{cfr}, thereby producing a distorted reduced signal u such that the signal outputted from the PA 208 becomes closer to the signal inputted to the DPD unit 206. Here, the DPD unit 206 aims to minimize the error of the output of the PA 208 towards y_{cfr} instead of y_{d}. Thus, as shown in FIG. 5, the signal outputted from the PA 208 after performing the DPD processing is closer to the ideal signal y as compared to the signal outputted from the PA 208 without performing the DPD processing. The PA 208 may be configured to receive the distorted reduced signal u and to amplify it, thereby producing an output signal y.

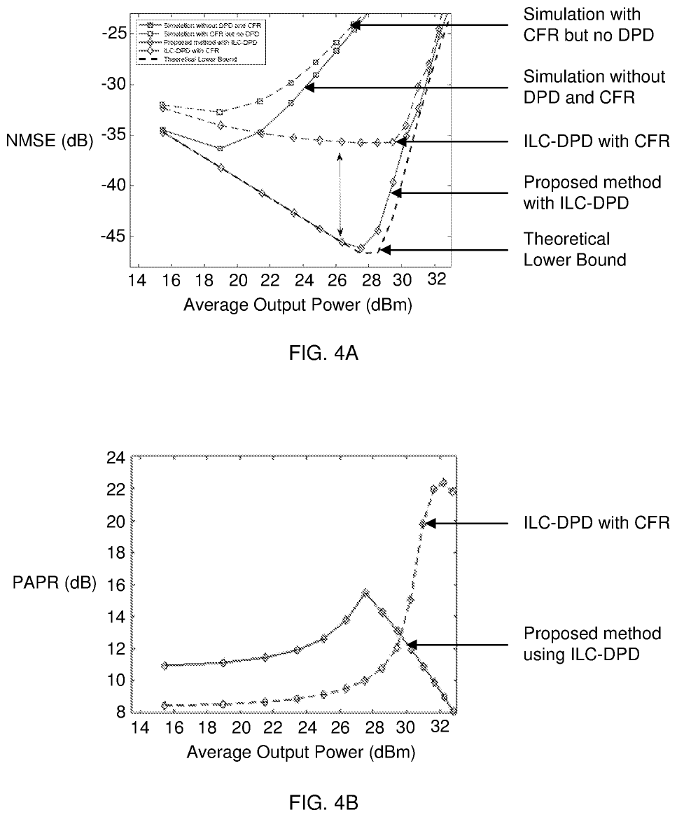

As shown in FIG. 5, there is a large difference between the desired signal output y and the signal output from the PA 208 with the DPD processing. Thus, including the CFR unit 204 before the DPD unit 206 creates an error which will not be compensated because the DPD unit 206 only aims to reproduce the clipped signal y_{cfr}. This causes an offset in terms of normalized mean squared error (NMSE) that prevents the PA unit 208 from reaching the lower bound of the NMSE as illustrated in FIG. 4A.

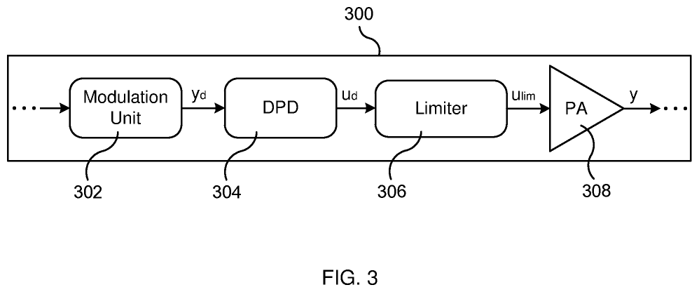

FIG. 3 shows an improved radio transmitter 300 according to some embodiments of this disclosure. The radio transmitter 300 may be included in the base station 102 and/or the UE 104.

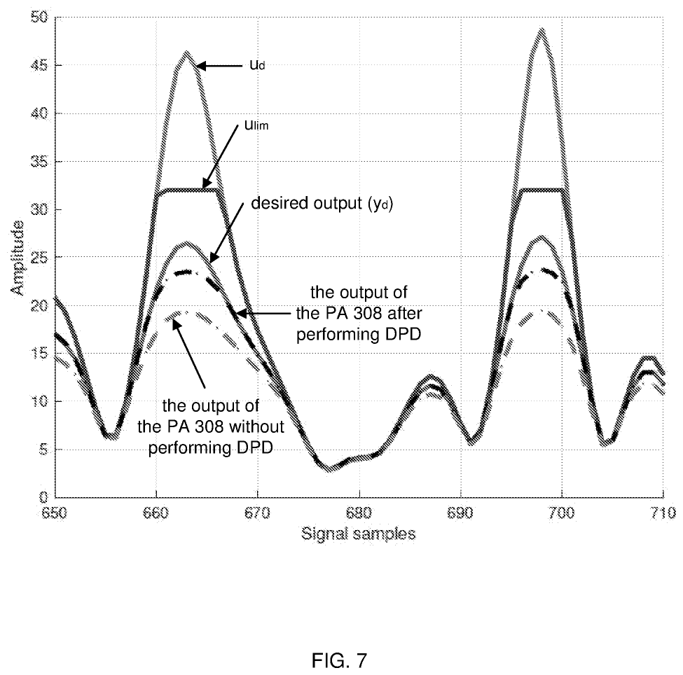

The radio transmitter 300 may include a modulation unit 302, a DPD unit 304, a limiter 306, and a PA 308. Each of the modulation unit 302, the DPD unit 304, the limiter 306, and the PA 308 may be formed of a plurality of parts or one integrated component. FIG. 7 shows exemplary signals inputted to and/or outputted from the modulation unit 302, the DPD unit 304, the limiter 306, and/or the PA 308.

Like the modulation unit 202, the modulation unit 302 may be an OFDM unit or other modulator. The DPD unit 304 is configured to receive the signal y_{d} generated by the modulation unit 302 and distort the received signal y_{d}, thereby producing a distorted signal u_{d}. According to some embodiments, the DPD unit 304 may distort the received input signal y_{d} by applying a polynominal function to the received input signal. For example, the DPD unit 304 may apply to the received input signal y_{d} the polynominal function of u_{d}=a₁y_{d}+a₃y_{d}|y_{d}|²+a₅y_{d}|y_{d}|⁴+ . . . , where y_{d}(d=1, . . . ,N) are samples of inputs to the DPD unit 304 and u_{d}(d=1, . . . ,N) are samples of outputs of the DPD unit 304.

According to some embodiments of this disclosure, the coefficients (e.g., a₁, a₃, a₅, . . . ) of the polynominal function may be determined using a learning algorithm (e.g., a regression-based learning). For example, signals outputted from the PA 308 may be used as samples for regression-based learning and the samples are fed back to the DPD unit 304. Based on the received samples, the DPD unit 304 may determine the coefficients (e.g., a₁, a₃, a₅, . . . ) of the polynominal function using the regression-based learning. Example(s) of regression-based learning model of a predistorter is disclosed in C. Eun and E. Powers, “A New Volterra Predistorter Based on the Indirect Learning Architecture”, IEEE Transactions on Signal Processing, vol. 45, no. 1, pp. 223-227, 1997.

In some embodiments of this disclosure, the parameters of the DPD unit 304 may be obtained using the Indirect Learning Architecture (ILA). The indirect learning means that the parameters of the DPD unit 304 are estimated indirectly.

The algorithm used by the DPD unit 304 may adopt a weighted criterion as to not to invert or to compensate samples of which values are above a clipping threshold. If the samples of which values are above the clipping threshold are not weighted (i.e., if they are inverted or compensated), they may have a negative impact on the overall performance of the DPD unit 304.

As shown in FIG. 7, the distorted signal u_{d} outputted from the DPD unit 304 may have amplitude that is too high for the PA 308 to handle if the distorted signal u_{d} is inputted directly to the PA 308. Such signal may cause the PA 308 to overdrive and potentially damage the PA 308.

Accordingly, in the radio transmitter 300 shown in FIG. 3, the limiter 306 is provided after the DPD unit 304.

The limiter 306 may receive the distorted input signal ua and generate a limited signal uₗᵢₘ based on the received distorted input signal u_{d}. In generating the limited signal uₗᵢₘ, the limiter 306 may clip the portions of the distorted input signal u_{d} that are equal to or greater than a clipping threshold (denoted A). For example, in FIG. 7, the limiter 306 may clip the portion of the input signal u_{d}, which has an amplitude value that is greater than or equal to a maximum threshold value (e.g., 32) such that the amplitude of the signal outputted from the limiter 306 stays below the maximum threshold value.

For example, the limiter 306 may apply the following function to the distorted input signal u_{d} to generate the limited signal uₗᵢₘ.

$$f ( {y}_{in} ) = \{ \begin{matrix}{y}_{in} , & \vert {y}_{in} \vert < A \\ A {e}^{i ∠ {y}_{in}} , & \vert {y}_{in} \vert \geq A\end{matrix} ,$$

where yᵢₙ is the input to the limiter 306 and A is the clipping threshold. i∠yᵢₙ is the expression indicating that the phase of the input signal yᵢₙ is maintained even after the function is applied to the input signal yᵢₙ.

The clipping level of the limiter 306 may be calibrated as to fit the compression behavior of the PA 308 for best performance. For example, the limiter may be calibrated to fit the PA's saturation point. If the clipping level is set too low, the available average output power will decrease and energy efficiency will suffer. On the other hand, if the clipping threshold is set too high or if the limiter is not used, the safety of the PA may be at risk. Thus, the limiter 306 protects the PA 306 from high peaks. Also it becomes transparent once the DPD 304 reaches the NMSE-optimal operation.

As shown in FIG. 7, the configuration of the radio transmitter 300 shown in FIG. 3 allows reproducing a desired output signal at the output of the PA 308 while the limiter 306 protects the PA 308 against excessively large peaks at the input and guarantees that the NMSE-optimal PA function is achieved.

Therefore, the configuration shown in FIG. 3 allows maximizing the output power of the PA 308 with minimal impact on EVM and/or NMSE. Furthermore, removing the CFR frees up computational resources and reduces the latency as the CFR is commonly a major contributor of the radio latency.

FIG. 4A shows simulated NMSE performances of different configurations for a PA. The different configurations involve selective use of a CFR unit, a DPD unit, and/or a limiter. As shown in the figure, the configuration according to some embodiments of this disclosure (i.e., using a limiter and iterative learning control (ILC)-DPD unit) allows achieving the lower bound of the NMSE. In contract, the NMSE of the configuration shown in FIG. 2 (i.e., the configuration using a CFR unit followed by a ILC-DPD unit) is much deviated from the NMSE lower bound.

FIG. 4B shows simulated input PAPRs as seen by the PA 208 and by the PA 308. As shown in the figure, while the input PAPR as seen by the PA 208 in the configuration shown in FIG. 2 rapidly increases as the average output power increases, the input PAPR as seen by the PA 308 in the configuration shown in FIG. 3 decreases after a certain point as the average output power increases.

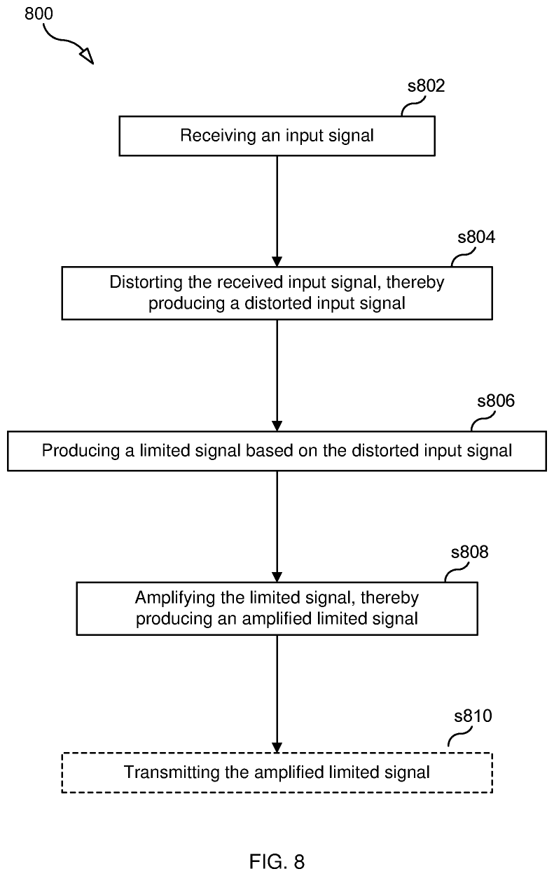

FIG. 8 is a flow chart illustrating a process 800 for efficient amplifier operation. Process 800 may be performed by radio transceiver 102 and/or 104 and begin in step s802.

Step s802 comprises receiving an input signal.

Step s804 comprises distorting the received input signal, thereby producing a distorted input signal.

Step s806 comprises producing a limited signal based on the distorted input signal.

Step s808 comprises amplifying the limited signal, thereby producing an amplified limited signal.

Step s810 comprises transmitting the amplified limited signal.

In some embodiments, producing the limited signal based on the distorted input signal comprises (i) determining whether a value of the distorted input signal is equal to or above a threshold value and (ii) as a result of determining that the value of the distorted input signal is equal to or above the threshold value, clipping the distorted input signal.

In some embodiments, the limited signal is equal to f(yᵢₙ), where yᵢₙ is the distorted input signal, and f(yᵢₙ) is equal to

$$f ( {y}_{in} ) = \{ \begin{matrix}{y}_{in} , & \vert {y}_{in} \vert < A \\ A {e}^{i ∠ {y}_{in}} , & \vert {y}_{in} \vert \geq A\end{matrix} ,$$

where A is a threshold value.

In some embodiments, amplifying the limited signal comprises amplifying the limited signal using a power amplifier, and the threshold value is set according to a maximum operating point of the power amplifier.

In some embodiments, distorting the received input signal comprises applying a polynominal function to the received input signal, thereby producing the distorted input signal.

In some embodiments, amplifying the limited signal comprises amplifying the limited signal using a power amplifier, and coefficients of the polynominal function are determined using regression-based learning based on feedbacks from an output of the power amplifier.

In some embodiments, the radio transceiver device is a base station.

In some embodiments, the radio transceiver device is a user equipment (UE).

While various embodiments are described herein, it should be understood that they have been presented by way of example only, and not limitation. Thus, the breadth and scope of this disclosure should not be limited by any of the above-described exemplary embodiments. Moreover, any combination of the above-described elements in all possible variations thereof is encompassed by the disclosure unless otherwise indicated herein or otherwise clearly contradicted by context.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel.

1. A radio transceiver device, the radio transceiver device comprising:
a distorting unit configured to receive an input signal and distort the received input signal, thereby producing a distorted input signal;
a limiter configured to receive the distorted input signal and produce a limited signal based on the received distorted input signal; and
a power amplifier configured to receive the limited signal and amplify the limited signal, thereby producing an amplified limited signal.

2. The radio transceiver device of claim 1, wherein producing the limited signal based on the received distorted input signal comprises (i) determining whether a value of the distorted input signal is equal to or above a threshold value and (ii) as a result of determining that the value of the distorted input signal is equal to or above the threshold value, clipping the distorted input signal.

3. The radio transceiver device of claim 1, wherein the limited signal is equal to f(yᵢₙ), where yᵢₙ is the distorted input signal, and f(yᵢₙ) is equal to
$$f ( {y}_{in} ) = \{ \begin{matrix}{y}_{in} , & \vert {y}_{in} \vert < A \\ A {e}^{i ∠ {y}_{in}} , & \vert {y}_{in} \vert \geq A\end{matrix} ,$$
where A is a threshold value.

4. The radio transceiver device of claim 2, wherein the threshold value is set according to a maximum operating point of the power amplifier.

5. The radio transceiver device of claim 1, wherein the distorting unit is a digital pre-distortion (DPD) unit, and distorting the received input signal comprises applying a polynominal function to the received input signal, thereby producing the distorted input signal.

6. The radio transceiver device of claim 5, wherein coefficients of the polynominal function are determined using regression-based learning based on feedbacks from an output of the power amplifier.

7. The radio transceiver device of claim 1, wherein the radio transceiver device is a base station.

8. The radio transceiver device of claim 1, wherein the radio transceiver device is a user equipment (UE).

9. The radio transceiver device of claim 1, wherein the radio transceiver device is configured to transmit the amplified limited signal.

10. A method performed by a radio transceiver device, the method comprising:
receiving an input signal;
distorting the received input signal, thereby producing a distorted input signal;
producing a limited signal based on the distorted input signal; and
amplifying the limited signal, thereby producing an amplified limited signal.

11. The method of claim 10, wherein producing the limited signal based on the distorted input signal comprises (i) determining whether a value of the distorted input signal is equal to or above a threshold value and (ii) as a result of determining that the value of the distorted input signal is equal to or above the threshold value, clipping the distorted input signal.

12. The method of claim 10, wherein
the limited signal is equal to f(yᵢₙ), where yᵢₙ is the distorted input signal, and f(yᵢₙ) is equal to
$$f ( {y}_{in} ) = \{ \begin{matrix}{y}_{in} , & \vert {y}_{in} \vert < A \\ A {e}^{i ∠ {y}_{in}} , & \vert {y}_{in} \vert \geq A\end{matrix} ,$$
where A is a threshold value.

13. The method of claim 11, wherein
amplifying the limited signal comprises amplifying the limited signal using a power amplifier, and
the threshold value is set according to a maximum operating point of the power amplifier.

14. The method of claim 10, wherein
distorting the received input signal comprises applying a polynominal function to the received input signal, thereby producing the distorted input signal.

15. The method of claim 14, wherein
amplifying the limited signal comprises amplifying the limited signal using a power amplifier, and
coefficients of the polynominal function are determined using regression-based learning based on feedbacks from an output of the power amplifier.

16. The method of claim 10, wherein the radio transceiver device is a base station.

17. The method of claim 10, wherein the radio transceiver device is a user equipment (UE).

18. The method of claim 10, further comprising:
transmitting the amplified limited signal.
